(19) United States
(12) Patent Application Publication
(10) Pub. No.: US 2025/0280647 A1
(43) Pub. Date: Sep. 4, 2025

(54) DISPLAY DEVICE

(71) Applicant: LG Display Co., Ltd., Seoul (KR)

(72) Inventor: SuJeong LEE, Seoul (KR)

(73) Assignee: LG Display Co., Ltd., Seoul (KR)

(21) Appl. No.: 19/064,409

(22) Filed: Feb. 26, 2025

(30) Foreign Application Priority Data
Feb. 29, 2024 (KR) 10-2024-0030042

(51) Int. Cl. H10H 29/855; G06F 3/041; H10H 29/854

(52) U.S. Cl. CPC H10H 29/8552; G06F 3/04164; H10H 29/854

(57) ABSTRACT

A display device includes a substrate which includes a display area in which a plurality of pixels including a plurality of sub pixels representing different colors is disposed and a non-display area which encloses the display area, a first light emitting diode and a second light emitting diode disposed in each of the plurality of sub pixels, a first optical member which is disposed so as to overlap an emission area of the first light emitting diode and provides a viewing angle with a first value, a plurality of second optical members which are disposed so as to overlap an emission area of the second light emitting diode and provides a viewing angle with a second value which is lower than the first value, and a protective film disposed on the first optical member.

### CROSS-REFERENCE TO RELATED APPLICATIONS

This application claims the priority of Korean Patent Application No. 10-2024-0030042 filed on Feb. 29, 2024, in the Korean Intellectual Property Office, the disclosure of which is incorporated herein by reference.

### BACKGROUND

### Technical Field

The present disclosure relates to a display device, and more particularly, to a display device which is capable of controlling a viewing angle and has excellent display quality and reliability.

### Discussion of the Related Art

An organic light emitting diode (OLED) which is a self-emitting device includes an anode, a cathode, and an organic compound layer formed therebetween. The organic compound layer is formed of a hole transport layer (HTL), an emission layer (EML), and an electron transport layer (ETL). When a driving voltage is applied to the anode and the cathode, holes which pass through the hole transport layer HTL and electrons which pass through the electron transport layer ETL move to the emission layer EML to form excitons so that the emission layer EML generates visible rays. The organic light emitting display device includes an organic light emitting diode which is a self-emitting device, unlike a liquid crystal display device including a backlight which is a separate light source and is used for various purposes with a fast response speed, high luminous efficiency, high luminance, and a large viewing angle.

There is no limitation on a viewing angle of the organic light emitting display device, but recently, it has been requested to limit the viewing angle for a reason, such as protection of privacy and information. However, the limitation on the viewing angle varies depending on whether to drive or whether passengers in a driver's seat and a front passenger's seat watch, so that it is necessary to selectively switch the viewing angle. Further, in some countries, media played in the front passenger's seat is prohibited from being exposed to the driver's seat so that it is necessary to selectively switch the viewing angle.

In accordance with the above-described demands, a display device which includes a viewing angle control element and a touch sensor unit on a display panel to adjust a viewing angle has been developed. However, in the display device with this structure, the viewing angle control element and the touch sensor unit are manufactured on separate base members, respectively, and then laminated so that the structure is complex and reduction in the thickness of the display device is limited. Accordingly, a technology which embeds a viewing angle control element and a touch sensor unit in the display panel is actively being developed.

### SUMMARY

Accordingly, embodiments of the present disclosure are directed to a display device that substantially obviates one or more of the problems due to limitations and disadvantages of the related art.

An aspect of the present disclosure is to provide a display device which is capable of selectively controlling a viewing angle.

Another aspect of the present disclosure is to provide a display device in which a luminance difference between modes is minimized in a function of selectively providing different viewing angle modes.

Still another aspect of the present disclosure is to provide a display device which solves yellowing defects generated at an outer edge by suppressing moisture and oxygen permeating from the outer edge.

Still another aspect of the present disclosure is to provide a display device with an excellent reliability.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate which includes a display area in which a plurality of pixels including a plurality of sub pixels representing different colors is disposed and a non-display area which encloses the display area; a first light emitting diode and a second light emitting diode disposed in each of the plurality of sub pixels; a first optical member which is disposed so as to overlap an emission area of the first light emitting diode and provides a viewing angle with a first value; a plurality of second optical members which are disposed so as to overlap an emission area of the second light emitting diode and provides a viewing angle with a second value which is lower than the first value; and a protective film disposed on the first optical member.

Other detailed matters of the exemplary embodiments are included in the detailed description and the drawings.

In the display device according to the present disclosure, the viewing angle may be selectively controlled.

In the display device according to the present disclosure, a phenomenon that a content which should not be shared by a driver of a vehicle is shared is improved to minimize a safety issue for the user.

In the display device according to the present disclosure, in the function of selectively providing different viewing angle modes, a luminance difference between modes is minimized to provide an excellent viewing angle control function and display quality.

In the display device according to the present disclosure, moisture and oxygen permeating from the outer edge are suppressed to improve the yellowing defect generated in a non-display area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is an exemplary view of a display device according to an exemplary embodiment of the present disclosure;

FIG. 2 is a functional block diagram of a display device according to an exemplary embodiment of the present disclosure;

FIG. 3 is a circuit diagram illustrating an example of a pixel circuit of a display device according to an exemplary embodiment of the present disclosure;

FIG. 4 is an enlarged plan view illustrating placement of an optical member included in one pixel of a display device according to an exemplary embodiment of the present disclosure;

FIG. 5 is a cross-sectional view taken along the line A-A′ of FIG. 4;

FIG. 6 is a cross-sectional view taken along the line B-B′ of FIG. 4;

FIG. 7 is a cross-sectional view of a non-display area of a display device according to an exemplary embodiment of the present disclosure;

FIG. 8 is a cross-sectional view of a display device according to another exemplary embodiment of the present disclosure;

FIG. 9 is a cross-sectional view of a display device according to still another exemplary embodiment of the present disclosure; and

FIG. 10 is a graph illustrating a yellowing degree evaluation result of a panel according to Exemplary Embodiments 3-1 and 3-2 and Comparative Embodiment 3.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

In the meantime, the term of optical member used in the present disclosure may be defined as a lens.

Hereinafter, the present disclosure will be described in detail with reference to the drawings.

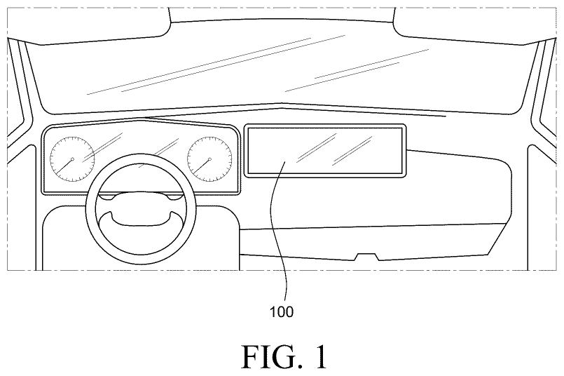

FIG. 1 is an exemplary view of a display device according to an exemplary embodiment of the present disclosure.

The display device 100 may be disposed in at least a part of a dash board of a vehicle. The dash board of the vehicle includes a configuration disposed in front surfaces of front seats (for example, a driver seat and a front passenger seat) of the vehicle. For example, on the dash board of the vehicle, an input configuration for manipulating various functions (for example, an air-conditioner, an audio system, or a navigation system) in the vehicle may be disposed.

In the exemplary embodiment, the display device 100 is disposed on the dash board of the vehicle to operate as an input unit which manipulates at least a part of various functions of the vehicle. The display device 100 may provide various information related to the vehicle, for example, operation information of the vehicle (for example, a current speed of the vehicle, a remaining fuel amount, or a mileage) or information about parts of the vehicle (for example, a damage level of a vehicle tire).

In an exemplary embodiment, the display device 100 may be disposed across the driver seat and the front passenger seat disposed in the front seats of the vehicle. A user of the display device 100 may include a driver of the vehicle and a passenger riding on the front passenger seat. Both the vehicle driver and the passenger may use the display device 100.

In the exemplary embodiment, only a part of the display device 100 may be illustrated in FIG. 1. The display device 100 illustrated in FIG. 1 may represent a display panel, among various configurations included in the display device 100. Specifically, for example, the display device 100 illustrated in FIG. 1 may represent at least a part of a display area and a non-display area of the display panel. Among the configurations of the display device 100, configurations other than the parts illustrated in FIG. 1 may be mounted inside the vehicle (or at least a part of the inside of the vehicle).

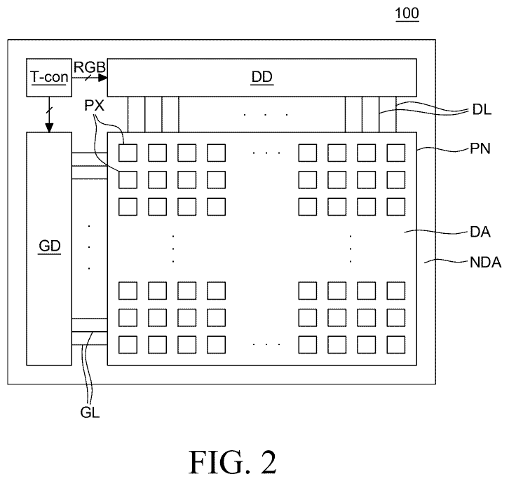

FIG. 2 is a functional block diagram of a display device according to an exemplary embodiment of the present disclosure.

As the display device according to the exemplary embodiment of the present disclosure, an electroluminescent display device may be applied. The electroluminescent display device may use an organic light emitting diode (OLED) display device, a quantum dot light emitting diode display device, or an inorganic light emitting diode display device.

Referring to FIG. 2, the display device 100 may include a display panel PN, a data driving circuit DD, a gate driving circuit GD, and a timing controller T-con.

In the exemplary embodiment, the display panel PN may generate images to be provided to the user. For example, the display panel PN may generate and display images to be provided to the user through a plurality of pixels PX in which the pixel circuits are disposed.

The data driving circuit DD, the gate driving circuit GD, and the timing controller T-con may provide signals for operations of the pixels PX through signal lines. The signal lines may include data lines DL and gate lines GL, for example.

In some cases, the display device may further include a power unit. In this case, a signal for the operation of the pixel PX may be supplied through the power line which connects the power unit and the display panel PN. According to the exemplary embodiment, the power unit may supply power to the data driving circuit DD and the gate driving circuit GD. The data driving circuit DD and the gate driving circuit GD may be driven based on the power supplied from the power unit.

For example, the data driving circuit DD may apply a data signal to each pixel PX through the data lines DL. The gate driving circuit GD may apply a gate signal to each pixel PX through the gate lines GL. The power unit may supply a power voltage to each pixel PX through the power voltage supply lines.

The timing controller T-con may control the data driving circuit DD and the gate driving circuit GD. For example, the timing controller T-con rearranges digital video data input from the outside in accordance with a resolution of the display panel PN to supply the digital video data to the data driving circuit DD.

The data driving circuit DD converts digital video data input from the timing controller T-con into an analog data voltage based on the data control signal to supply the converted analog data voltage to the plurality of data lines DL.

The gate driving circuit GD may generate a scan signal and an emission signal (or an emission control signal) based on the gate control signal. The gate driving circuit GD may include a scan driver and an emission signal driver. The scan driver may generate a scan signal in a row sequential manner to drive at least one scan line connected to each pixel row to supply the scan signal to the scan lines. The emission signal driver may generate an emission signal in a row sequential manner to drive at least one emission signal line connected to each pixel row to supply the emission signal to the emission signal lines.

According to the exemplary embodiment, the gate driving circuit GD may be disposed in the display panel PN in a gate-driver in panel (GIP) manner. For example, the gate driving circuit GD is divided into a plurality of circuits to be disposed on at least two side surfaces of the display panel PN.

The display panel PN may include a display area DA and a non-display area NDA.

The display area DA may include a plurality of pixels PX. In the pixel PX, a plurality of data lines (for example, data lines DL of FIG. 2) and a plurality of gate lines (for example, gate lines GL of FIG. 2) intersect and sub pixels are disposed in intersecting areas. Each sub pixel included in one pixel PX may emit different color light. For example, the pixel PX uses three sub pixels to implement blue, red, and green. However, this is not limited thereto and, in some cases, the pixel PX may further include a sub pixel for further implementing a specific color (for example, white).

In the pixel PX, an area which implements blue is referred to as a blue sub pixel, an area which implements red is referred to as a red sub pixel, and an area which implements green is referred to as a green sub pixel.

In the exemplary embodiment, the pixel PX may include a plurality of sub pixels. Each of the plurality of sub pixels may be divided into a first optical member area and a second optical member area which provide different viewing angles. For example, one pixel PX may include a first optical member area which supplies light in a first range to form a first viewing angle and a second optical member area which supplies light in a second range to form a second viewing angle. The first range may be larger than the second range.

The non-display area NDA may be disposed around the display area DA. Various components for driving the pixel circuit disposed in the pixel PX may be disposed in the non-display area NDA. For example, at least a part of the gate driving circuit GD may be disposed in the non-display area NDA. The non-display area NDA may be referred to as a bezel area.

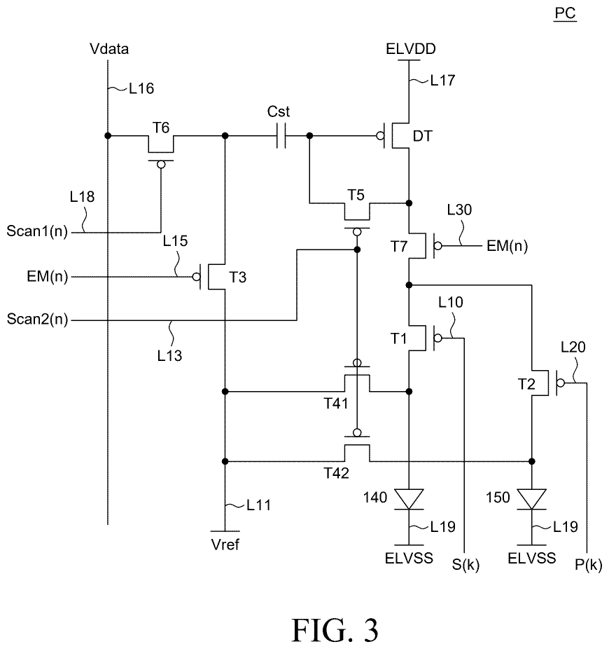

FIG. 3 is a circuit diagram illustrating an example of a pixel circuit of a display device according to an exemplary embodiment of the present disclosure. The pixel PX may include a plurality of sub pixels which represent different colors and pixel circuits PC corresponding to the plurality of sub pixels. FIG. 3 illustrates an example of a pixel circuit PC for one sub pixel disposed in the pixel PX.

Referring to FIG. 3, the pixel circuit PC may include nine transistors and one capacitor.

The pixel circuit PC may include a first transistor T1, a second transistor T2, a third transistor T3, a 4-1-th transistor T41, a 4-2-th transistor T42, a fifth transistor T5, a sixth transistor T6, a seventh transistor T7, a driving transistor DT, and a capacitor Cst.

At least some of nine transistors included in the pixel circuit PC may be an n-type transistor or a p-type transistor. In the case of the p-type transistor, a low level voltage of each driving signal may refer to a voltage which turns on a TFT and a high level voltage of each driving signal may refer to a voltage which turns off the TFT.

Here, the low level voltage may correspond to a predetermined voltage which is lower than the high level. For example, the low level voltage may include a voltage corresponding to a range of −8 V to −12 V. The high level voltage may correspond to a predetermined voltage which is higher than the low level voltage. For example, the high level voltage may include a voltage corresponding to the range of 12 V to 16 V. According to the exemplary embodiment, the low level voltage may be referred to as a first voltage and the high level voltage may be referred to as a second voltage. In this case, the first voltage may be lower than the second voltage. However, the ranges of the low level voltage and the high level voltage are illustrative, but are not limited thereto.

Here, a first electrode or a second electrode of the transistor to be described below may refer to a source electrode or a drain electrode. However, the terms of the first electrode and the second electrode are terms for distinguishing the electrodes, but do not limit what corresponds to each electrode. Further, in each electrode, the first electrode may not refer to the same electrode. For example, a first electrode of the first transistor T1 may refer to a source electrode of the first transistor T1 and a first electrode of the sixth transistor T6 may refer to a drain electrode of the sixth transistor T6.

In the exemplary embodiment, the driving transistor DT may be connected to the first transistor T1 connected to the first light emitting diode 140 and the second transistor T2 connected to the second light emitting diode 150. For example, the second electrode of the driving transistor DT may be connected to the first transistor T1 and the second transistor T2.

In the exemplary embodiment, the driving transistor DT may be connected to a first power line L17 which supplies a high potential power voltage ELVDD. For example, the first electrode of the driving transistor DT may be connected to the first power line L17. When the driving transistor DT is turned on, the high potential power voltage ELVDD supplied through the first power line L17 may be transmitted from the first electrode to the second electrode of the driving transistor DT.

In the exemplary embodiment, the first transistor T1 may be connected to at least one of the first light emitting diode 140, the second transistor T2, the 4-1-th transistor T41, and the seventh transistor T7.

For example, the first electrode of the first transistor T1 may be connected to at least one of the second transistor T2 and the seventh transistor T7. The seventh transistor T7 may be connected to the driving transistor DT and the fifth transistor T5. The second electrode of the first transistor T1 may be connected to at least one of the first light emitting diode 140 and the 4-1-th transistor T41. The gate electrode of the first transistor T1 may be connected to a first control line L10. The first transistor T1 may be turned on or off by a first control signal S(k) supplied through the first control line L10. When the first transistor T1 is turned on, the voltage through the driving transistor DT and the seventh transistor T7 may be input to the first light emitting diode 140 (for example, an anode electrode of the first light emitting diode 140).

Here, the first control signal S(k) may include a k-th first control signal which is supplied to a k-th column as the pixel circuit PC is disposed in a k-th (k is a positive integer) column. The first control signal S(k) is supplied by a mode controller (or a mode control circuit) and may control the driving (or emission) of the first light emitting diode 140 in which the first optical member (that is, a first lens) is disposed.

In the exemplary embodiment, the second transistor T2 may be connected to at least one of the second light emitting diode 150, the first transistor T1, the 4-2-th transistor T42, and the seventh transistor T7.

For example, the first electrode of the second transistor T2 may be connected to at least one of the first transistor T1 and the seventh transistor T7. The second electrode of the second transistor T2 may be connected to at least one of the 4-2-th transistor T42 and the second light emitting diode 150. The seventh transistor T7 may be connected to the driving transistor DT and the fifth transistor T5. The gate electrode of the second transistor T2 may be connected to a second control line L20. The second transistor T2 may be turned on or off by a second control signal P(k) supplied through the second control line L20. When the second transistor T2 is turned on, the voltage through the driving transistor DT and the seventh transistor T7 may be input to the second light emitting diode 150 (for example, an anode electrode of the second light emitting diode 150).

Here, the second control signal P(k) may include a k-th second control signal which is supplied to a k-th column as the pixel circuit PC is disposed in a k-th (k is a positive integer) column. The second control signal P(k) is supplied by a mode controller (or a mode control circuit) and may control the driving (or emission) of the second light emitting diode 150 in which the second optical member (that is, a second lens) is disposed.

In one exemplary embodiment, the first optical member may be disposed on the first light emitting diode 140. A viewing angle of the area in which the first light emitting diode 140 is disposed may correspond to a first value by the first optical member. For example, the viewing angle of the area in which the first light emitting diode 140 is disposed may be equal to or larger than the first value. The second optical member may be disposed on the second light emitting diode 150. A viewing angle of the area in which the second light emitting diode 150 is disposed may correspond to a second value by the second optical member. The second value may be smaller than the first value. For example, the viewing angle of the area in which the second light emitting diode 150 is disposed may be equal to or smaller than the second value.

In the exemplary embodiment, the area in which the first light emitting diode 140 of the pixel circuit PC is disposed may have a viewing angle of a first value to supply light to a range corresponding to the front passenger seat and the driver seat next to the front passenger seat. The area in which the second light emitting diode 150 is disposed may have a viewing angle of a second value to supply light to a range corresponding to the front passenger seat.

In the exemplary embodiment, the third transistor T3 may be connected to at least one of the 4-1-th transistor T41, the 4-2-th transistor T42, the sixth transistor T6, and the capacitor Cst.

For example, the first electrode of the third transistor T3 may be connected to the sixth transistor T6 and the capacitor Cst. The second electrode of the third transistor T3 may be connected to the 4-1-th transistor T41 and the 4-2-th transistor T42. The gate electrode of the third transistor T3 may be connected to the emission signal line L15 which supplies the emission signal EM (n). The emission signal EM (n) may correspond to an n-th emission signal EM (n) supplied to an n-th row as the pixel circuit PC is disposed in an n-th (n is a positive integer) pixel row. The third transistor T3 may be turned on or off by the emission signal EM(n). The second electrode of the third transistor T3 may be connected to the reference voltage line L11 which supplies a reference voltage Vref, for example, the second power line.

In the exemplary embodiment, the 4-1-th transistor T41 may be connected to at least one of the first transistor T1, the third transistor T3, and the first light emitting diode 140.

For example, the first electrode of the 4-1-th transistor T41 may be connected to the third transistor T3. The second electrode of the 4-1-th transistor T41 may be connected to the first transistor T1 and the first light emitting diode 140. The gate electrode of the 4-1-th transistor T41 may be connected to an n-th second scan line L13. Therefore, the 4-1-th transistor T41 may be supplied with an n-th second scan signal Scan2(n) and may be turned on or off by the n-th second scan signal Scan2(n).

In the exemplary embodiment, the 4-2-th transistor T42 may be connected to at least one of the second transistor T2, the third transistor T3, and the second light emitting diode 150. For example, the first electrode of the 4-2-th transistor T42 may be connected to the third transistor T3. The second electrode of the 4-2-th transistor T42 may be connected to the second transistor T2 and the second light emitting diode 150. The gate electrode of the 4-2-th transistor T42 may be connected to an n-th second scan line L13. Therefore, the 4-2-th transistor T42 may be supplied with an n-th second scan signal Scan2(n) and may be turned on or off by the n-th second scan signal Scan2(n).

In the exemplary embodiment, the fifth transistor T5 may be connected to at least one of the driving transistor DT, the 4-1-th transistor T41, the 4-2-th transistor T42, the capacitor Cst, and the seventh transistor T7.

For example, the first electrode of the fifth transistor T5 may be connected to the driving transistor DT and the capacitor Cst. The second electrode of the fifth transistor T5 may be connected to the driving transistor DT and the seventh transistor T7. The gate electrode of the fifth transistor T5 may be connected to the n-th second scan line L13 which supplies the second scan signal Scan2(n) in the n-th row. The fifth transistor T5 may be supplied with the n-th second scan signal Scan2(n) and may be turned on or off by the n-th second scan signal Scan2(n).

According to the exemplary embodiment, the n-th first scan line L18 may supply the n-th first scan signal. In this case, the n-th first scan signal may be supplied to the gate electrode of the sixth transistor T6. The n-th second scan line L13 may supply the n-th second scan signal. In this case, the n-th second scan signal may be supplied to gate electrodes of the 4-1-th transistor T41, the 4-2-th transistor T42, and the fifth transistor T5.

In the exemplary embodiment, the sixth transistor T6 may be connected to at least one of the third transistor T3 and the capacitor Cst.

For example, the first electrode of the sixth transistor T6 may be connected to the third transistor T3 and the capacitor Cst. The second electrode of the sixth transistor T6 may be connected to the data line L16 which supplies a data voltage Vdata. The gate electrode of the sixth transistor T6 may be connected to the n-th first scan line L18 which supplies the n-th first scan signal Scan1(n). The sixth transistor T6 may be supplied with an n-th first scan signal Scan1(n) and may be turned on or off by the n-th first scan signal Scan1(n). When the sixth transistor T6 is turned on, the data voltage Vdata may be transmitted from the second electrode to the first electrode.

In the exemplary embodiment, the seventh transistor T7 may be connected to at least one of the first transistor T1, the second transistor T2, the fifth transistor T5, and the driving transistor DT.

For example, the first electrode of the seventh transistor T7 may be connected to at least one of the fifth transistor T5 and the driving transistor DT. The second electrode of the seventh transistor T7 may be connected to at least one of the first transistor T1 and the second transistor T2. The gate electrode of the seventh transistor T7 may be connected to the emission signal line L30 which supplies the emission signal EM(n). The seventh transistor T7 may be turned on or off based on the emission signal EM(n). When the seventh transistor T7 is turned on, a voltage (or a current) may be supplied from the first electrode to the second electrode of the seventh transistor T7.

In the exemplary embodiment, the first light emitting diode 140 and/or the second light emitting diode 150 may be connected to the third power line L19 which supplies a low potential power voltage ELVSS. For example, the cathode electrode of the first light emitting diode 140 and the cathode electrode of the second light emitting diode 150 may be connected to the third power line L19 to be supplied with the low potential power voltage ELVSS.

According to the exemplary embodiment, the low potential power voltage may include a ground voltage (for example, 0 V). For example, the cathode electrode of the first light emitting diode 140 and the cathode electrode of the second light emitting diode 150 may be supplied with a voltage corresponding to the ground, but are not limited thereto.

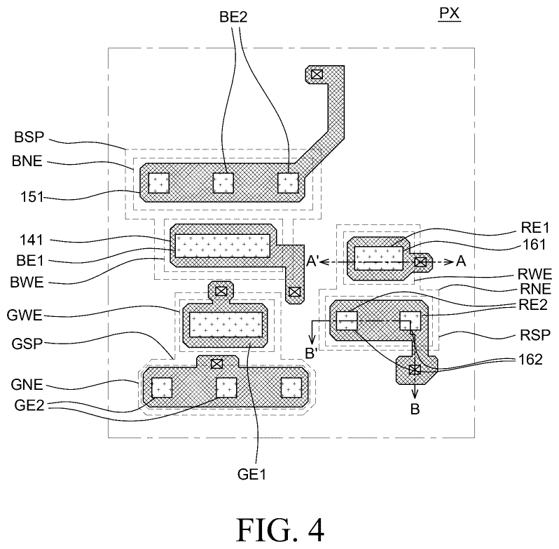

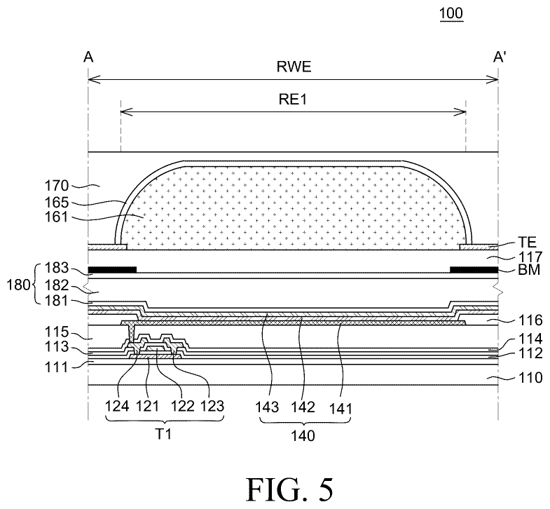

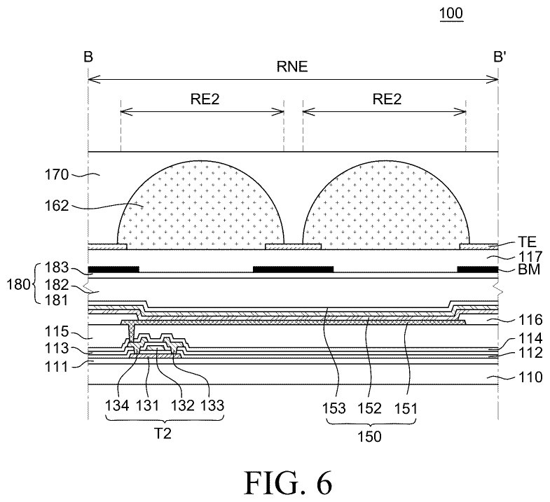

FIG. 4 is an enlarged plan view illustrating placement of an optical member included in one pixel of a display device according to an exemplary embodiment of the present disclosure. FIG. 5 is a cross-sectional view taken along the line A-A′ of FIG. 4. FIG. 6 is a cross-sectional view taken along the line B-B′ of FIG. 4. FIG. 4 illustrates a plane of a pixel PX when three sub pixels RSP, GSP, and BSP are disposed in one pixel PX. FIG. 5 illustrates a cross-section taken along the line A-A′ of FIG. 4 and FIG. 6 illustrates a cross-section taken along the line B-B′ of FIG. 4. However, even though in FIGS. 5 and 6, for the convenience of description, only an area corresponding to a first optical member area RWE and a second optical member area RNE of the red sub pixel RSP, among the plurality of sub pixels RSP, GSP, and BSP, is illustrated, the other sub pixels GSP and BSP may also be formed with the same configuration.

First, referring to FIG. 4, the pixel PX may include a plurality of sub pixels RSP, GSP, and BSP which represent different colors. For example, the pixel PX may include a blue sub pixel BSP which implements blue, a red sub pixel RSP which implements red, and a green sub pixel GSP which implements green. According to the exemplary embodiment, the blue sub pixel BSP may correspond to a first sub pixel, the red sub pixel RSP may correspond to a second sub pixel, and the green sub pixel GSP may correspond to a third sub pixel. The pixel circuit PC may correspond to each of the sub pixels RSP, GSP, and BSP. A corresponding pixel circuit PC (for example, the pixel circuit PC of FIG. 3) may be disposed in each of the sub pixels RSP, GSP, and BSP.

The sub pixels RSP, GSP, and BSP may include first optical member areas RWE, GWE, and BWE and second optical member areas RNE, GNE, and BNE which provide different viewing angles, respectively.

The second optical member areas RNE, GNE, and BNE of the sub pixels RSP, GSP, and BSP may operate independently from the first optical member areas RWE, GWE, and BWE of the corresponding pixels PX. For example, in each sub pixel RSP, GSP, BSP, the first light emitting diode 140 (for example, the first light emitting diode 140 of FIG. 3) and the second light emitting diode 150 (for example, the second light emitting diode 150 of FIG. 3) may be disposed. The first light emitting diode 140 is located in the first optical member areas RWE, GWE, and BWE of the corresponding sub pixels RSP, GSP, and BSP and the second light emitting diode 150 is located in the second optical member areas RNE, GNE, and BNE of the corresponding sub pixels RSP, GSP, and BSP.

In one pixel PX, the first light emitting diode 140 and the second light emitting diode 150 may be disposed in every first optical member area RWE, GWE, BWE and second optical member area RNE, GNE, BNE of the plurality of sub pixels RSP, GSP, and BSP.

For example, in one pixel PX, a first light emitting diode 140 disposed in the first optical member area RWE of the red sub pixel RSP, a second light emitting diode 150 disposed in the second optical member area RNE of the red sub pixel RSP, a first light emitting diode 140 disposed in the first optical member area GWE of the green sub pixel GSP, a second light emitting diode 150 disposed in the second optical member area GNE of the green sub pixel GSP, a first light emitting diode 140 disposed in the first optical member area BWE of the blue sub pixel BSP, and a second light emitting diode 150 disposed in the second optical member area BNE of the blue sub pixel BSP may be disposed.

Referring to FIG. 4, in the first optical member areas RWE, GWE, and BWE of the sub pixels RSP, GSP, and BSP, a first optical member 161 which is disposed so as to overlap the first emission area RE1, GE1, BE1 of the first light emitting diode 140 is disposed. In the second optical member areas RNE, GNE, and BNE of the sub pixels RSP, GSP, and BSP, a plurality of second optical members 162 which are disposed so as to overlap the second emission area RE2, GE2, BE2 of the second light emitting diode 150 is disposed. At this time, the first optical member areas RWE, GWE, and BWE may have a viewing angle of a first value and the second optical member areas RNE, GNE, and BNE may have a viewing angle of a second value which is larger than the viewing angle of the first value. In the meantime, the specific placement structure of the first optical member 161 and the plurality of second optical members 162 will be described below with reference to FIGS. 5 and 6 together.

Referring to FIGS. 5 and 6 together, the display device 100 according to the exemplary embodiment of the present disclosure may include a substrate 110, a buffer layer 111, a gate insulating layer 112, an interlayer insulating layer 113, a lower protective layer 114, an overcoat layer 115, a first transistor T1, a second transistor T2, a first light emitting diode 140, a second light emitting diode 150, an encapsulation member 180, a touch insulating layer 117, a touch electrode TE, a first optical member 161, a second optical member 162, a protective film 165, and an organic layer 170.

The substrate 110 may be disposed so as to support other components disposed on the substrate 110. The substrate 110 may include an insulating material. The substrate 110 may include a transparent material. For example, the substrate 110 may include glass or plastic, but is not limited thereto.

The buffer layer 111 may be located between the substrate 110 and a driving part of each sub pixel RSP, GSP, BSP. The buffer layer 111 may suppress the contamination due to the substrate 110 in a process of forming the driving part. For example, a top surface of the substrate 110 which faces the driving part of each sub pixel RSP, GSP, BSP may be covered by the buffer layer 111. The driving part of each sub pixel RSP, GSP, BSP may be disposed on the buffer layer 111.

The buffer layer 111 may include an insulating material. For example, the buffer layer 111 may include an inorganic insulating material, such as silicon oxide (SiOx) or silicon nitride (SiNx). The buffer layer 111 may have a multilayered structure. For example, the buffer layer 111 may have a laminated structure of a film formed of silicon nitride (SiNx) and a film formed of silicon oxide (SiOx), but is not limited thereto.

The gate insulating layer 112 may be located on the buffer layer 111. The gate insulating layer 112 may extend between a semiconductor layer and a gate electrode of the transistor. For example, the gate electrodes 122 and 132 of the first transistor T1 and the second transistor T2 may be insulated from the semiconductor layers 121 and 131 of the first transistor T1 and the second transistor T2, by the gate insulating layer 112. The gate insulating layer 112 may cover the first semiconductor layer 121 and the second semiconductor layer 131 of each sub pixel RSP, GSP, BSP. The gate electrodes 122 and 132 of the first transistor T1 and the second transistor T2 may be located on the gate insulating layer 112.

The gate insulating layer 112 may include an insulating material. For example, the gate insulating layer 112 may include an inorganic insulating material, such as silicon oxide (SiO) or silicon nitride (SiN). The gate insulating layer 112 may include a material having a high permittivity. For example, the gate insulating layer 112 may include a High-K material, such as hafnium oxide (HfO). The gate insulating layer 112 may have a multi-layered structure, but is not limited thereto.

The interlayer insulating layer 113 may be located on the gate insulating layer 112. The interlayer insulating layer 113 may extend between the gate electrode and the source electrode and between the gate electrode and the drain electrode of the transistor. For example, the source electrodes 123 and 133 and the drain electrodes 124 and 134 of the first transistor T1 and the second transistor T2 may be insulated from the gate electrodes 122 and 132 by the interlayer insulating layer 113. The interlayer insulating layer 113 may cover the gate electrodes 122 and 132 of the first transistor T1 and the second transistor T2. The source electrodes 123 and 133 and the drain electrodes 124 and 134 of each sub pixel RSP, GSP, BSP may be located on the interlayer insulating layer 113. The gate insulating layer 112 and the interlayer insulating layer 113 may expose a source region and a drain region of each semiconductor layer 121, 131.

The interlayer insulating layer 113 may include an insulating material. For example, the interlayer insulating layer 113 may include an inorganic insulating material, such as silicon oxide (SiO) or silicon nitride (SiN). The interlayer insulating layer 113 may be located on the gate insulating layer 112, but is not limited thereto.

The lower protective layer 114 may be located on the interlayer insulating layer 113. The lower protective layer 114 may suppress the damage to the driving part due to the external moisture and shocks. The lower protective layer 114 may extend along surfaces of the first transistor T1 and the second transistor T2. The lower protective layer 114 may be in contact with the interlayer insulating layer 113 at the outside of the driving part located in each sub pixel RSP, GSP, BSP.

The lower protective layer 114 may include an insulating material. For example, the lower protective layer 114 may include an inorganic insulating material, such as silicon oxide (SiO) or silicon nitride (SiN), but is not limited thereto.

The overcoat layer 115 may be located on the lower protective layer 114. The overcoat layer 115 may remove a step caused by the driving part of each sub pixel RSP, GSP, BSP. For example, a top surface of the overcoat layer 115 which is opposite to the substrate 110 may be a flat surface.

The overcoat layer 115 may include an insulating material. The overcoat layer 115 may include a material different from that of the lower protective layer 114. For example, the overcoat layer 115 may include an organic insulating material, but is not limited thereto.

The first transistor T1 may include a first semiconductor layer 121, a first gate electrode 122, a first source electrode 123, and a first drain electrode 124.

For example, the first semiconductor layer 121 may be located between the buffer layer 111 and the gate insulating layer 112 and the first gate electrode 122 may be located between the gate insulating layer 112 and the interlayer insulating layer 113. The first source electrode 123 and the first drain electrode 124 may be located between the interlayer insulating layer 113 and the lower protective layer 114. The first gate electrode 122 may overlap a channel region of the first semiconductor layer 121. The first source electrode 123 may be electrically connected to the source region of the first semiconductor layer 121. The first drain electrode 124 may be electrically connected to the drain region of the first semiconductor layer 121.

The second transistor T2 may include a second semiconductor layer 131, a second gate electrode 132, a second source electrode 133, and a second drain electrode 134.

For example, the second semiconductor layer 131 may be located on the same layer as the first semiconductor layer 121 and the second gate electrode 132 may be located on the same layer as the first gate electrode 122. The second source electrode 133 and the second drain electrode 134 may be located on the same layer as the first source electrode 123 and the first drain electrode 124.

The first transistor T1 may be formed simultaneously with the second transistor T2.

The first light emitting diode 140 and the second light emitting diode 150 of each sub pixel RSP, GSP, BSP may be located on the overcoat layer 115 of each sub pixel RSP, GSP, BSP. For example, a first lower electrode 141 of the first light emitting diode 140 may be electrically connected to the first drain electrode 124 (or the first source electrode 123) of the first transistor T1 through a contact hole which passes through the lower protective layer 114 and the overcoat layer 115. A second lower electrode 151 of the second light emitting diode 150 may be electrically connected to the second drain electrode 134 (or the second source electrode 133) of the second transistor T2 through a contact hole which passes through the lower protective layer 114 and the overcoat layer 115.

The first light emitting diode 140 may emit light representing a specific color. For example, the first light emitting diode 140 may include a first lower electrode 141, a first emission layer 142, and a first upper electrode 143 which are sequentially laminated on the substrate 110. At this time, the first lower electrode 141 may be an anode electrode of the first light emitting diode 140 and the first upper electrode 143 may be a cathode electrode of the first light emitting diode 140.

The first lower electrode 142 may be formed of a transparent conductive material, such as indium tin oxide (ITO) or indium zinc oxide (IZO), but is not limited thereto.

If necessary, optionally, the first lower electrode 141 may further include a reflective layer below a transparent conductive layer which is formed of a transparent conductive material or may be formed with a multilayered structure in which a reflective layer is disposed between the plurality of transparent conductive layers, but is not limited thereto. The reflective layer may include a material having a high reflectance. For example, the first lower electrode 141 may further include a reflective layer which is formed of metal, such as aluminum (Al) and silver (Ag), but is not limited thereto.

The first emission layer 142 may generate light with luminance corresponding to a voltage difference between the first lower electrode 141 and the first upper electrode 143. For example, the first emission layer 142 may include an emission material layer (EML) including an emission material. The emission material may include an organic material, an inorganic material, or a hybrid material.

The first emission layer 142 may have a multi-layered structure. For example, the first emission layer 142 may further include at least one of a hole injection layer HIL, a hole transport layer HTL, an electron transport layer ETL, and an electron injection layer EIL.

The first upper electrode 143 may include a conductive material. The first upper electrode 143 may include a different material from that of the first lower electrode 141. A transmittance of the first upper electrode 143 may be higher than a transmittance of the first lower electrode 141. For example, the first upper electrode 143 may be a transparent electrode formed of a transparent conductive material, such as ITO and IZO. Alternatively, the first upper electrode 143 may be a transparent electrode in which the metal material is formed with a very thin thickness. Accordingly, in the display device 100 according to the exemplary embodiment of the present disclosure, light generated by the first emission layer 142 may be emitted through the first upper electrode 143.

The second light emitting diode 150 may implement the same color as the first light emitting diode 140 disposed in the same sub pixel RSP, GSP, BSP. For example, the second light emitting diode 150 may include a second lower electrode 151, a second emission layer 152, and a second upper electrode 153 which are sequentially laminated on the substrate 110. At this time, the second lower electrode 151 may be an anode electrode of the second light emitting diode 150 and the second upper electrode 153 may be a cathode electrode of the second light emitting diode 150.

The second lower electrode 151 includes the same technical feature as the first lower electrode 141 so that a redundant description will be omitted.

Referring to FIGS. 5 and 6, the second emission layer 152 may correspond to the first emission layer 142 and the second upper electrode 153 may correspond to the first upper electrode 143. For example, the second emission layer 152 and the second upper electrode 153 may be formed for the second light emitting diode 150 with the same structure as the first emission layer 142 and the first upper electrode 143 of the first light emitting diode 140. For example, the emission layers 142 and 152 and the upper electrodes 143 and 153 of the first light emitting diode 140 and the second light emitting diode 150 may be formed to have the same structure. However, it is not limited thereto and, in some cases, at least a partial configuration of the emission layers 142 and 152 and the upper electrodes 143 and 153 of the first light emitting diode 140 and the second light emitting diode 150 may be formed to be different.

In the exemplary embodiment, the second emission layer 152 may be spaced apart from the first emission layer 142. Therefore, in the display device according to the exemplary embodiment of the present disclosure, light emission by a leakage current may be suppressed.

According to the exemplary embodiment of the present disclosure, in the display device 100, light may be generated by only one of the first emission layer 142 and the second emission layer 152 by the selection of the user or according to a predetermined condition.

The second lower electrode 151 of each sub pixel RSP, GSP, BSP may be spaced apart from the first lower electrode 141 of the corresponding sub pixel RSP, GSP, BSP. For example, a bank insulating layer 116 may be located between the first lower electrode 141 and the second lower electrode 151 of each sub pixel RSP, GSP, BSP. The bank insulating layer 116 may include an insulating material. For example, the bank insulating layer 116 may include an organic insulating material. The bank insulating layer 116 may include a material different from that of the overcoat layer 115, but is not limited thereto.

The second lower electrode 151 of each sub pixel RSP, GSP, BSP may be insulated from the first lower electrode 141 of the corresponding sub pixel RSP, GSP, BSP by the bank insulating layer 116. For example, the bank insulating layer 116 may cover an edge of the first lower electrode 141 and an edge of the second lower electrode 151 located in each sub pixel RSP, GSP, BSP.

The bank insulating layer 116 may divide an emission area of the first light emitting diode 140 and an emission area of the second light emitting diode 150. For example, the emission area of the first light emitting diode 140 may be divided by an edge area of the first lower electrode 141 covered by the bank insulating layer 116. The emission area of the second light emitting diode 150 may be divided by an edge area of the second lower electrode 151 covered by the bank insulating layer 116. At this time, referring to FIG. 4, a size of the emission area of the first light emitting diode 140 divided in each sub pixel RSP, GSP, BSP may be larger than a size of the emission area of the second light emitting diode 150, but is not limited thereto.

The first emission layer 142 and the first upper electrode 143 of the first light emitting diode 140 located in each sub pixel RSP, GSP, BSP may be disposed on the first lower electrode 141 and the bank insulating layer 116. Specifically, the first emission layer 142 and the first upper electrode 143 may be laminated on a partial area of the first lower electrode 141 exposed by the bank insulating layer 116 and the bank insulating layer 116. The second emission layer 152 and the second upper electrode 153 of the second light emitting diode 150 located in each sub pixel RSP, GSP, BSP may be disposed on the second lower electrode 151 and the bank insulating layer 116. Specifically, the second emission layer 152 and the second upper electrode 153 may be laminated on a partial area of the second lower electrode 151 exposed by the bank insulating layer 116 and the bank insulating layer 116.

The second upper electrode 153 of each sub pixel RSP, GSP, BSP may be electrically connected to the first upper electrode 143 of the corresponding sub pixel RSP, GSP, BSP. For example, a voltage applied to the second upper electrode 153 of the second light emitting diode 150 located in each sub pixel RSP, GSP, BSP may be equal to a voltage applied to the first upper electrode 143 of the first light emitting diode 140 located in the corresponding sub pixel RSP, GSP, BSP. The second upper electrode 153 of each sub pixel RSP, GSP, BSP may include the same material as the first upper electrode 143 of the corresponding sub pixel RSP, GSP, BSP. For example, the second upper electrode 153 of each sub pixel RSP, GSP, BSP may be formed simultaneously with the first upper electrode 143 of the corresponding sub pixel RSP, GSP, BSP. The second upper electrode 153 of each sub pixel RSP, GSP, BSP extends to a top surface of the bank insulating layer 116 to be in direct contact with the first upper electrode 143 of the corresponding sub pixel RSP, GSP, BSP. Luminance of the first optical member areas RWE, GWE, and BWE and luminance of the second optical member areas RNE, GNE, and BNE located in each sub pixel RSP, GSP, BSP may be controlled by a driving current generated in the corresponding sub pixel RSP, GSP, BSP.

The encapsulation member 180 may be located on the first light emitting diode 140 and the second light emitting diode 150 of each sub pixel RSP, GSP, BSP. The encapsulation member 180 may suppress the damage to the light emitting diodes 140 and 150 due to moisture and shocks from the outside. The encapsulation member 180 may have a multi-layered structure. For example, the encapsulation member 180 may include a first encapsulation layer 181, a second encapsulation layer 182, and a third encapsulation layer 183 which are sequentially laminated, but the exemplary embodiments of the present disclosure are not limited thereto.

The first encapsulation layer 181, the second encapsulation layer 182, and the third encapsulation layer 183 may include an insulating material. The second encapsulation layer 182 may include a material different from that of the first encapsulation layer 181 and the third encapsulation layer 183. For example, the first encapsulation layer 181 and the third encapsulation layer 183 are inorganic encapsulation layers including an inorganic insulating material and the second encapsulation layer 182 may include an organic encapsulation layer including an organic insulating material. Therefore, the encapsulation member 180 may efficiently suppress the damage to the light emitting diodes 140 and 150 of the display device 100 due to the moisture and shocks from the outside.

A black matrix BM may be disposed on the encapsulation member 180. The black matrix BM may be disposed between the plurality of sub pixels RSP, GSP, and BSP to reduce color mixture of the plurality of sub pixels RSP, GSP, and BSP. Therefore, the black matrix BM may be disposed so as to overlap the bank insulating layer 116.

The touch insulating layer 117 is disposed on the black matrix BM. The touch insulating layer 117 is disposed between the encapsulation member 180 and the black matrix BM and the touch electrode TE to insulate the touch electrode TE.

The touch insulating layer 117 may include an insulating material. For example, the touch insulating layer 117 may include an organic insulating material or an inorganic insulating material, but is not limited thereto.

A plurality of touch electrodes TE may be located on the touch insulating layer 117. The plurality of touch electrodes TE may be disposed above the first light emitting diode 140 and the second light emitting diode 150 in the display area DA. The plurality of touch electrodes TE may be disposed on the touch insulating layer 117 to be spaced apart from each other. The plurality of touch electrodes TE may be configured to sense external touch input using a user's finger, a touch pen, or the like.

Referring to FIGS. 5 and 6, the plurality of touch electrodes TE is disposed so as to overlap the bank insulating layer 116 and the black matrix BM. Accordingly, the plurality of touch electrodes TE may be configured to minimize the limitation of a path of light generated by the first light emitting diode 140 and the second light emitting diode 150.

For example, the plurality of touch electrodes TE may include a metal material, such as titanium (Ti), aluminum (Al), silver (Ag), copper (Cu), and a magnesium-silver alloy (Mg:Ag), but is not limited thereto.

In the meantime, a touch buffer layer may be further disposed between the encapsulation member 180 and the touch electrode TE, but is not limited thereto. Further, a touch bridge electrode may be further disposed on the encapsulation member 180 in addition to the touch electrode TE, but is not limited thereto.

Referring to FIGS. 5 and 6, the first optical member 161 and the plurality of second optical members 162 may be located on the encapsulation member 180 and the touch electrode TE of each sub pixel RSP, GSP, BSP. The first optical member 161 and the plurality of second optical members 162 may be disposed so as to cover edges of the plurality of touch electrodes TE. The first optical member 161 may be disposed so as to correspond to the first light emitting diode 140 and the plurality of second optical members 162 may be disposed so as to correspond to the second light emitting diode 150. The optical member may also be defined as the term of lens. That is, the first optical member 161 disposed so as to correspond to the first light emitting diode 140 may be referred to as a first lens and the plurality of second optical members 162 disposed so as to correspond to the second light emitting diode 150 may be referred to as second lenses.

The first optical member 161 may be located on the first optical member areas RWE, GWE, and BWE of the sub pixels RSP, GSP, and BSP.

For example, light generated by the first light emitting diode 140 of the sub pixels RSP, GSP, and BSP may be emitted through the first optical members 161 of the corresponding sub pixel RSP, GSP, and BSP.

The first optical member 161 may have a shape that does not limit light of at least one direction. For example, a planar shape of the first optical member 161 located in each sub pixel RSP, GSP, BSP may have a bar shape which extends in the first direction. For example, the first optical member 161 may be a semicylindrical lens.

In this case, a traveling direction of light emitted from the first optical member area RWE, GWE, BWE of each sub pixel RSP, GSP, BSP may not be limited in the first direction. For example, contents (or images) provided through the first optical member areas RWE, GWE, and BWE of each pixel PX may be shared by surrounding people which are adjacent to the user in the first direction. When the contents are provided through the first optical member areas RWE, GWE, and BWE, the contents are provided at a first viewing angle range which is larger than a second viewing angle range supplied by the second optical member areas RNE, GNE, and BNE and this may be referred to as a first mode.

The plurality of second optical members 162 may be located on the second optical member areas RNE, GNE, and BNE of each sub pixel RSP, GSP, BSP.

For example, light generated by the second light emitting diode 150 of the sub pixels RSP, GSP, and BSP may be emitted through the plurality of second optical members 162 of the corresponding sub pixel RSP, GSP, BSP. At this time, a traveling direction of light which passes through the plurality of second optical members 162 may be limited to the first direction and/or the second direction.

For example, a planar shape of the plurality of second optical members 162 located in the sub pixels RSP, GSP, and BSP may be a square shape. That is, the plurality of second optical members 162 may be hemispherical lenses. In this case, the traveling direction of light emitted from the second optical member areas RNE, GNE, and BNE of the sub pixels RSP, GSP, and BSP may be limited to the first direction and the second direction. However, the planar shape of the plurality of second optical members 162 may be a circular shape, but is not limited thereto.

The contents supplied by the second optical member areas RNE, GNE, and BNE of the sub pixels RSP, GSP, and BSP may not be shared by the people around the user. When the contents are provided through the second optical member areas RNE, GNE, and BNE, the contents are provided at the second viewing angle range which is smaller than the first viewing angle range supplied by the first optical member areas RWE, GWE, and BWE and this may be referred to as a second mode.

An area of each sub pixel RSP, GSP, BSP in which the first optical member 161 is disposed may be referred to as a first emission area REI, GE1, BE1. For example, the first emission areas RE1, GE1, and BE1 may be areas in which the light generated by the first light emitting diode 140 is emitted through the first optical member 161.

An area of each sub pixel RSP, GSP, BSP in which the plurality of second optical members 162 is disposed may be referred to as a second emission area RE2, GE2, BE2. For example, the second emission areas RE2, GE2, and BE2 may be areas in which the light generated by the second light emitting diode 150 is emitted through the plurality of second optical members 162.

The first emission areas RE1, GE1, and BE1 included in the first optical member areas RWE, GWE, and BWE of the sub pixels RSP, GSP, and BSP may have a shape corresponding to the first optical members 161 located on the first optical member areas RWE, GWE, and BWE of the corresponding sub pixels RSP, GSP, and BSP. For example, the planar shape of the first emission areas RE1, GE1, and BE1 defined in the first optical member areas RWE, GWE, and BWE of the sub pixels RSP, GSP, and BSP may have a bar shape extending in the first direction.

The first optical member 161 located on the first optical member areas RWE, GWE, and BWE of the sub pixels RSP, GSP, and BSP may have the same size as the first emission areas RE1, GE1, and BE1 included in the first optical member areas RWE, GWE, and BWE of the corresponding sub pixels RSP, GSP, and BSP. Further, the first optical member 161 may have a size larger than the first emission areas RE1, GE1, and BE1 so that efficiency of light emitted from the first emission areas RE1, GE1, and BE1 of the sub pixels RSP, GSP, and BSP may be improved.

The plurality of second emission areas RE2, GE2, and BE2 included in the second optical member areas RNE, GNE, and BNE of the sub pixels RSP, GSP, and BSP may have a shape corresponding to the plurality of second optical members 162 located on the second optical member areas RNE, GNE, and BNE of the corresponding sub pixels RSP, GSP, and BSP. For example, a planar shape of the second emission areas RE2, GE2, and BE2 included in the second optical member areas RNE, GNE, and BNE of the sub pixels RSP, GSP, and BSP may have a polygonal or circular shape.

The plurality of second optical members 162 located on the second optical member areas RNE, GNE, and BNE of the sub pixels RSP, GSP, and BSP may have the same size as the second emission areas RE2, GE2, and BE2 included in the second optical member areas RNE, GNE, and BNE of the corresponding sub pixels RSP, GSP, and BSP. Further, the plurality of second optical members 162 may have a size larger than the second emission areas RE2, GE2, and BE2 so that efficiency of light emitted from the second emission areas RE2, GE2, and BE2 of the sub pixels RSP, GSP, and BSP may be improved.

In the exemplary embodiment, the first optical member area RWE, GWE, BWE of one sub pixel RSP, GSP, BSP may include one first emission area RE1, GE1, BE1. In the exemplary embodiment, the second optical member area RNE, GNE, BNE of one sub pixel RSP, GSP, BSP may include the plurality of second emission areas RE2, GE2, and BE2.

In the exemplary embodiment, one first optical member 161 may be disposed on the first optical member area RWE, GWE, BWE of one sub pixel RSP, GSP, BSP. The plurality of second optical members 162 may be disposed on the second optical member area RNE, GNE, BNE of one sub pixel RSP, GSP, BSP.

In the exemplary embodiment, the size of the first emission area REI, GE1, BE1 may vary in each sub pixel RSP, GSP, BSP. For example, the first emission area BE1 of the blue sub pixel BSP may have a different size from the first emission area GE1 of the green sub pixel GSP and have a different size from the first emission area RE1 of the red sub pixel RSP. A size of the first emission area BE1 of the blue sub pixel BSP may be larger than the size of the first emission area GE1 of the green sub pixel GSP. A size of the first emission area GE1 of the green sub pixel GSP may be larger than the size of the first emission area RE1 of the red sub pixel RSP. Accordingly, in the display device according to the exemplary embodiment of the present disclosure, the efficiency deviation of the first light emitting diode 140 located on the first optical member areas RWE, GWE, and BWE of the sub pixels RSP, GSP, and BSP may be compensated by the size of the first emission areas RE1, GE1, and BE1 defined in the first optical member areas RWE, GWE, and BWE of each sub pixel RSP, GSP, BSP.

In the exemplary embodiment, an area of each of the second emission areas RE2, GE2, and BE2 located in the second optical member areas RNE, GNE, and BNE of the plurality of sub pixels RSP, GSP, and BSP may be specified by a specific value. For example, the area of each of the second emission areas RE2, GE2, and BE2 located in the second optical member areas RNE, GNE, and BNE may be implemented to be the same. The second emission areas RE2, GE2, and BE2 included in the second optical member areas RNE, GNE, and BNE of the plurality of sub pixels RSP, GSP, and BSP may have the same area as the second emission areas RE2, GE2, and BE2 included in the second optical member areas RNE, GNE, and BNE of the adjacent sub pixels RSP, GSP, and BSP.

In the exemplary embodiment, the number of the plurality of second emission areas RE2, GE2, and BE2 may vary in each sub pixel RSP, GSP, BSP. For example, the number of second emission areas BE2 defined in the second optical member area BNE of the blue sub pixel BSP and the number of second emission areas GE2 defined in the second optical member area GNE of the green sub pixel GSP may be larger than the number of second emission areas RE2 defined in the second optical member area RNE of the red sub pixel RSP. In this case, the efficiency deviation of the second light emitting diodes 150 located on the second optical member areas RNE, GNE, and BNE of the sub pixels RSP, GSP, and BSP may be compensated by the number of second emission areas RE2, GE2, and BE2 defined in the second optical member areas RNE, GNE, and BNE of each sub pixel RSP, GSP, BSP. In addition, the above-described efficiency deviation may be compensated by the protective film 165 disposed on the first optical member 161, which will be described below.

In the exemplary embodiment, the first optical member 161 and the second optical member 162 use a material having a high refractive characteristic to implement a viewing angle control function and a condensing effect of light emitted from the light emitting diodes 140 and 150. For example, the first optical member 161 and the second optical member 162 may be formed of a photo acrylate material. For example, the first optical member 161 and the second optical member 162 may include a fluorene-based monomer and an acrylic polymer. Specifically, for example, the first optical member 161 and the second optical member 162 may be formed with a composition including the above-described monomer and polymer, and a solvent and contents of the monomer and the polymer may be 30 wt % or more and 35 wt % or less with respect to 100 wt % of the composition. However, the present disclosure is not limited thereto. For example, the solvent may be selected from an organic solvent, such as PGMEA or PGME, but is not limited thereto. Further, the composition may further include additives such as antioxidants or UV absorbers (for example, 2-(5-tert-Butyl-2-hydroxyphenyl)benzotriazole) to improve reliability.

In th exemplary embodiment, an interval between adjacent optical members 161 and 162 may be 15 μm or larger and 25 μm or smaller and a length from a bottom surface to a top surface of each of the optical members 161 and 162 may be 7 μm or larger and 12 μm or smaller, but the present disclosure is not limited thereto.

In the exemplary embodiment, the protective film 165 may be disposed on the first optical member 161 of the sub pixel RSP, GSP, BSP. The protective film 165 may be formed to have a constant thickness along an upper surface of the first optical member 161. That is, the protective film 165 may be disposed so as to cover the entire surface of the first optical member 161.

As described above, when the content is provided through the first optical member areas RWE, GWE, and BWE, the content is provided in a first mode in which the content is provided in the first viewing angle range larger than the second viewing angle range provided by the second optical member areas RNE, GNE, and BNE. When the content is provided through the second optical member areas RNE, GNE, and BNE, the content is provided in a second mode in which the content is provided in the second viewing angle range smaller than the first viewing angle range provided by the first optical member areas RWE, GWE, and BWE.

At this time, a luminance difference between the first mode and the second mode occurs due to the difference in areas between the first optical member areas RWE, GWE, and BWE and the second optical member areas RNE, GNE, and BNE. Desirably, a luminance of 40% or higher is requested in the first mode and a luminance of 50% or higher is requested in the second mode. However, as described with reference to FIG. 4, there is a problem in that the luminance of the first mode is low due to the area difference between the first optical member areas RWE, GWE, and BWE and the second optical member areas RNE, GNE, and BNE.

In the exemplary embodiment, the protective film 165 is disposed on the first optical member 161 so that the luminance difference between the first mode and the second mode may be improved. When the protective film 165 is disposed on the first optical member 161, a low luminance of the first mode is improved to reduce the luminance difference between the first mode and the second mode. Accordingly, there are advantages of excellent viewing angle control characteristics and superior display quality with improved luminance.

In the exemplary embodiment, a refractive index of the protective film 165 may be 1.9 or larger and 2.2 or smaller. In this case, the first optical member 161 increases a light extraction efficiency so that the luminance in the first mode is improved to reduce the luminance difference between the first mode and the second mode, but the present disclosure is not limited thereto.

In the exemplary embodiment, the thickness of the protective film 165 may be 100 nm or larger and 200 nm or smaller. In this case, the luminance of the first mode is improved to reduce the luminance difference between the first mode and the second mode. When the thickness of the protective film 165 exceeds 200 nm, the luminance of the first mode may be reduced due to the light loss.

In the exemplary embodiment, the protective film 165 may be formed of an inorganic material or an organic material. Specifically, the protective film 165 may include one or more of inorganic materials, such as silicon nitride film (SiNx) or silicon oxide film (SiOx), or may be formed of an organic material such as parylene.

In the exemplary embodiment, the protective film 165 may be formed by vacuum deposition of the above-described inorganic material or organic material, but is not limited thereto.

In the present exemplary embodiment, it is illustrated that the protective film 165 is disposed on the first optical member 161, but is not limited thereto. The protective film 165 may be disposed to cover both the first optical member 161 and the second optical member 162 depending on a placement structure of the sub pixels RSP, GSP, and BSP or a design structure of the display device 100. In this case, the protective film 165 protects the first optical member 161 and the second optical member 162 from external moisture or oxygen to achieve more excellent reliability. Therefore, when more excellent reliability is requested according to the usage environment, the protective film 165 may be disposed not only on the first optical member 161, but also on the second optical member 162.

In the exemplary embodiment, the organic layer 170 may be located on the first optical member 161 and the plurality of second optical members 162 of the sub pixels RSP, GSP, and BSP. The organic layer 170 may include an insulating material. For example, the organic layer 170 may include an organic insulating material. A refractive index of the organic layer 170 may be smaller than a refractive index of the first optical member 161 and a refractive index of the second optical member 162 located in each sub pixel RSP, GSP, BSP. Accordingly, in the display device 100 according to the exemplary embodiment of the present disclosure, light which passes through the first optical member 161 and the second optical member 162 in each sub pixel RSP, GSP, BSP may not be reflected toward the substrate 110 due to the refractive index difference from the organic layer 170.

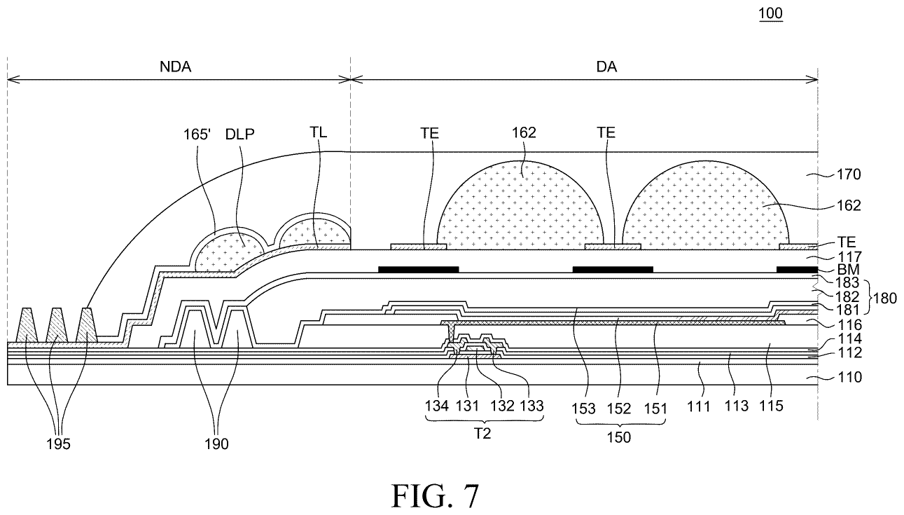

FIG. 7 is a cross-sectional view of a non-display area of a display device according to an exemplary embodiment of the present disclosure.

Referring to FIG. 7, each of the buffer layer 111, the gate insulating layer 112, the interlayer insulating layer 113, and the lower protective layer 114 may extend not only to the display area DA, but also to the non-display area NDA. The buffer layer 111, the gate insulating layer 112, the interlayer insulating layer 113, and the lower protective layer 114 may be substantially formed on the entire surface of the substrate 110.

In the non-display area NDA, a dam 190 which blocks the flow of the second encapsulation layer 182 which is formed of an organic insulating material, among the first encapsulation layer 181, the second encapsulation layer 182, and the third encapsulation layer 183 which configure the encapsulation member 180, may be disposed. The dam 190 is disposed on the substrate 110 as a closed curve which encloses the display area DA in the non-display area NDA. Specifically, the dam 190 may be disposed on the lower protective layer 114 which is formed to extend to the non-display area NDA. Further, the first encapsulation layer 181, the second encapsulation layer 182, and the third encapsulation layer 183 extend not only to the display area DA, but also to the non-display area NDA. The first encapsulation layer 181 and the third encapsulation layer 183 are disposed on the dam 190 and the flow of the second encapsulation layer 182 may be blocked by the dam 190. The dam 190 needs to be formed with a predetermined height or higher to block the flow of the second encapsulation layer 182. To this end, the dam 190 may be formed of at least one or more layers formed of an organic material. For example, the dam 190 may include a lower layer formed of the same material as the overcoat layer 115 and an upper layer formed of the same material as the bank insulating layer 116, but is not limited thereto. Even though in the drawing, a configuration with two dams 190 is illustrated, one or three or more dams 190 may be provided.

The touch insulating layer 117 may be disposed to extend not only to the display area DA, but also to the non-display area NDA. The touch insulating layer 117 may be disposed on the dam 190.

In the non-display area NDA, a plurality of touch routing lines TL which electrically connects the plurality of touch electrodes TE and a touch pad (not illustrated) may be disposed. The plurality of touch routing lines TL may be disposed on the touch insulating layer 117 in the same manner as the plurality of touch electrodes TE. The touch routing line TL may be disposed so as to extend from the non-display area NDA adjacent to the display area DA to the outer edge of the non-display area NDA. Therefore, the touch routing line TL may be connected to the touch pad (not illustrated) which is located at the outer edge of the non-display area NDA. The touch routing line TL electrically connects each of the plurality of touch electrodes TE disposed in the display area DA and the touch pad (not illustrated). One end of the touch pad (not illustrated) is connected to the touch routing line TL and the other end is connected to an external circuit such as a touch driver to receive a touch driving signal from the external circuit or transmit a touch sensing signal to the external circuit. Accordingly, the touch driving signal or the touch sensing signal may be transmitted to the touch electrode TE through the touch routing line TL.

In the exemplary embodiment, a plurality of dummy optical members DLP is disposed on the touch routing line TL. The plurality of dummy optical members DLP is located in the non-display area NDA to increase an inflow path of oxygen or moisture so that the permeation of oxygen or moisture into the display area DA may be delayed. Therefore, the yellowing phenomenon caused by the deterioration due to moisture or oxygen may be improved.

The plurality of dummy optical members DLP is disposed along the touch routing line TL with a constant interval. The plurality of dummy optical members DLP may be formed of the same material by the same process as the first optical member 161 and the second optical member 162 disposed in the display area DA. The plurality of dummy optical members DLP may be a semicylindrical lens or a hemispherical lens, but is not limited thereto. When the plurality of dummy optical members DLP is disposed on the inclined touch insulating layer 117 as described above, the flowability of the organic layer 170 having a high flowability may be controlled.

Even though in the drawing, the dummy optical member DLP and the first and second optical members 161 and 162 are illustrated to have different sizes, the present disclosure is not limited thereto. The dummy optical member DLP and the first and second optical members 161 and 162 may have the same size.

As described above, the dummy optical member DLP may include a fluorene-based monomer and an acrylic polymer. Fluorene-based monomer may undergo carbonylation, where some atom groups are replaced by carbonyl groups by oxygen or moisture. When the carbonylation occurs as described above, yellowing occurs in the dummy optical member DLP due to material degeneration.

Therefore, in the exemplary embodiment, a sub protective film 165′ is disposed on the dummy optical member DLP. The sub protective film 165′ may be disposed so as to cover the dummy optical member DLP disposed on the touch routing line TL. Specifically, the sub protective film 165′ may be disposed so as to cover the touch routing line TL and the dummy optical member DLP. The sub protective film 165′ may be disposed with a constant thickness along a surface of the touch routing line TL on which the dummy optical member DLP is disposed. As described above, the sub protective film 165′ is disposed on the dummy optical member DLP to suppress the degeneration of the dummy optical member DLP due to the moisture or oxygen permeating from the outside. Accordingly, the yellowing phenomenon generated due to the degeneration of the dummy optical member DLP in the outer edge portion of the display device 100 may be suppressed.

In the exemplary embodiment, the sub protective film 165′ may be formed of an inorganic material or an organic material. Specifically, the sub protective film 165′ may include one or more of inorganic materials, such as silicon nitride film (SiNx) or silicon oxide film (SiOx), or may be formed of an organic material such as parylene. These materials may suppress degeneration of dummy optical member DLP due to oxygen or moisture permeating from the outside by improving anti-moisture permeability and oxygen resistance without deteriorating optical properties such as transmittance or haze, and may further improve the yellowing defect.

In the exemplary embodiment, the thickness of the sub protective film 165′ may be 100 nm or larger and 200 nm or smaller. In this case, the deterioration of the dummy optical member DLP due to the oxygen or moisture may be suppressed without deteriorating the optical properties, such as transmittance or haze.

In the exemplary embodiment, the sub protective film 165′ may be formed by vacuum deposition of the above-described inorganic material or organic material, but is not limited thereto.

The sub protective film 165′ may be formed of the same material by the same process as the protective film 165 disposed on the first optical member 161 in the display area DA, but is not limited thereto.

A partition 195 is disposed along an outer periphery of the dam 190 in the non-display area NDA. The partition 195 may be disposed on the substrate 110 as a closed curve which encloses the dam 190. The partition 195 may be disposed between the touch pad (not illustrated) disposed at the outer edge of the non-display area NDA and the dam 190. For example, the partition 195 may be disposed on the touch routing line TL.

For example, the partition 195 may be formed of an organic material. A height of the partition 195 may be higher than a height of the dam 190 to suppress the organic layer 170 from flowing to the outer edge of the non-display area NDA in which the touch pad is located. Even though in the drawing, a configuration with three partitions 195 is illustrated, one or two partitions 195 may be provided.

The organic layer 170 is disposed to extend not only to the display area DA, but also to the non-display area NDA. In the non-display area NDA, the organic layer 170 may be disposed so as to cover the touch routing line TL and the dummy optical member DLP. The organic layer 170 may be disposed above the dam 190 and an end of the organic layer 170 may be disposed between the partition 195 and the dam 190.

In the display device, above a light emitting diode, a black matrix, and a touch electrode, all a first optical member and a plurality of second optical members may be disposed in one sub pixel to selectively provide different viewing angle modes to a user. The luminance difference is generated due to the area difference between the first optical member area and the second optical member area of the plurality of sub pixels.

The display device 100 according to the exemplary embodiment of the present disclosure includes a protective film 165 above the first optical member 161 having a relatively low luminance due to the area difference. Accordingly, the luminance of the first optical member areas RWE, GWE, and BWE of the plurality of sub pixels RSP, GSP, and BSP is improved so that the luminance difference due to the area difference between the first optical member area RWE, GWE, BWE and the second optical member area RNE, GNE, BNE may be reduced. Further, in the display device 100 according to the exemplary embodiment of the present disclosure, the sub protective film 165′ is disposed on the dummy optical member DLP in the non-display area NDA. The sub protective film 165′ protects the dummy optical member DLP from moisture or oxygen permeating from the outside to suppress degeneration of the dummy optical member DLP due to moisture or oxygen, thereby reducing the yellowing defect generated in the outer edge.

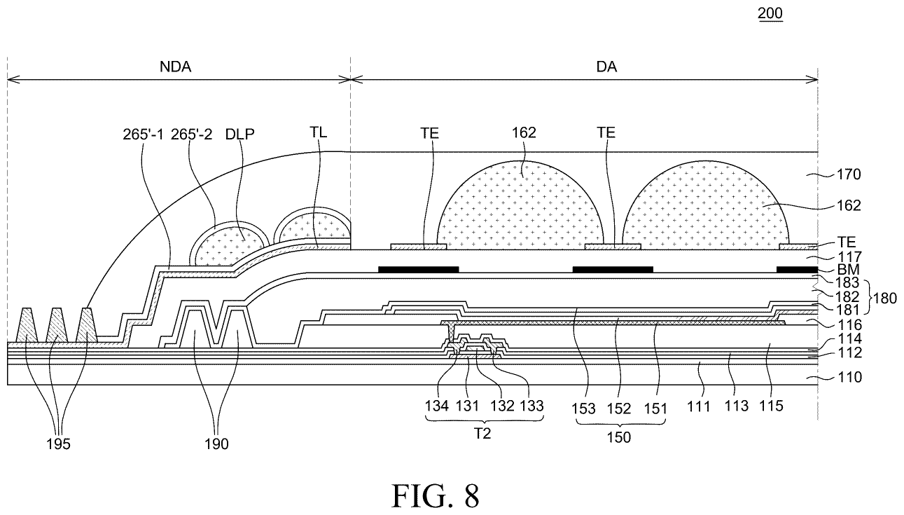

FIG. 8 is a cross-sectional view of a display device according to another exemplary embodiment of the present disclosure.

Referring to FIG. 8, a display device 200 according to another exemplary embodiment of the present disclosure may include a substrate 110, a buffer layer 111, a gate insulating layer 112, an interlayer insulating layer 113, a lower protective layer 114, an overcoat layer 115, a first transistor T1, a second transistor T2, a first light emitting diode 140, a second light emitting diode 150, an encapsulation member 180, a touch insulating layer 117, a touch electrode TE, a first optical member 161, a second optical member 162, a protective film 165, a dummy optical member DLP, a first sub protective film 265′-1, a second sub protective film 265′-2, an organic layer 170, a touch routing line TL, a dam 190, and a partition 195. The display device 200 is substantially the same as the display device 100 which has been described with reference to FIGS. 1 to 7 except that the sub protective film includes a first sub protective film and a second sub protective film, so that a description of repeated components will be omitted.

The display device 200 includes a first sub protective film 265′-1 and a second sub protective film 265′-2 disposed in the non-display area NDA. The first sub protective film 265′-1 is disposed on the touch routing line TL. The first sub protective film 265′-1 may be disposed so as to extend from the non-display area NDA adjacent to the display area DA to the outer edge of the non-display area NDA, but is not limited thereto.

Therefore, in the exemplary embodiment, the plurality of dummy optical members DLP are disposed on the first sub protective film 265′-1. The plurality of dummy optical members DLP may be spaced apart from the non-display area NDA adjacent to the display area DA to the outer edge of the non-display area NDA with a constant interval.

The second sub protective film 265′-2 is disposed on the dummy optical member DLP. The second sub protective film 265′-2 is in contact with a top surface of each of the plurality of dummy optical members DLP and has a shape corresponding to the top surface of each of the plurality of dummy optical members DLP. The second sub protective film 265′-2 may be formed with a constant thickness along the top surface of each of the plurality of dummy optical members DLP. Therefore, each of the plurality of dummy optical members DLP may be formed to be enclosed by the first sub protective film 265′-1 and the second sub protective film 265′-2.

The second sub protective film 265′-2 may be formed of the same material by the same process as the protective film 165 disposed on the first optical member 161 in the display area DA, but is not limited thereto.

As described above, an optical member, such as a dummy optical member may include a fluorene-based monomer and some atom groups thereof are degenerated due to oxygen or moisture to be replaced to a carbonyl group. The yellowing defect is caused by the carbonylation of the dummy optical member.

In the exemplary embodiment, each of the plurality of dummy optical members DLP is formed to be enclosed by the first sub protective film 265′-1 and the second sub protective film 265′-2 to protect the dummy optical member DLP from the moisture or oxygen flowing from the outside. Therefore, the deterioration of the dummy optical member DLP due to the moisture and oxygen is suppressed to further suppress the yellowing defect.

The first sub protective film 265′-1 and the second sub protective film 265′-2 may be formed of an inorganic material or an organic material. Specifically, the first sub protective film 265′-1 and the second sub protective film 265′-2 may include one or more of inorganic materials, such as silicon nitride film (SiNx) or silicon oxide film (SiOx), or may be formed of an organic material such as parylene. These materials suppress degeneration of dummy optical member DLP due to oxygen or moisture permeating from the outside by improving anti-moisture permeability and oxygen resistance without deteriorating optical properties such as transmittance or haze, and further improve the yellowing defect.

In the exemplary embodiment, a thickness of each of the first sub protective film 265′-1 and the second sub protective film 265′-2 may be 100 nm or larger and 200 nm or smaller. In this case, the deterioration of the dummy optical member DLP due to the oxygen or moisture may be suppressed without deteriorating the optical properties, such as transmittance or haze. In the exemplary embodiment, the first sub protective film 265′-1 and the second sub protective film 265′-2 may be formed by vacuum deposition of the above-described inorganic material or organic material, but are not limited thereto.

In the present exemplary embodiment, it is illustrated that the first sub protective film 265′-1 is disposed in the non-display area NDA, but is not limited thereto. If necessary, the first sub protective film 265′-1 extends to the display area DA to be disposed on the touch insulating layer 117 and the touch electrode TE. In this case, each of the first optical member 161 and the second optical member 162 may be disposed on the first sub protective film 265′-1. When the first sub protective film 265′-1 is disposed below the first optical member 161 and the second optical member 162 as described above, the first optical member 161 and the second optical member 162 are protected from moisture or oxygen permeating from the outside to further improve the reliability.

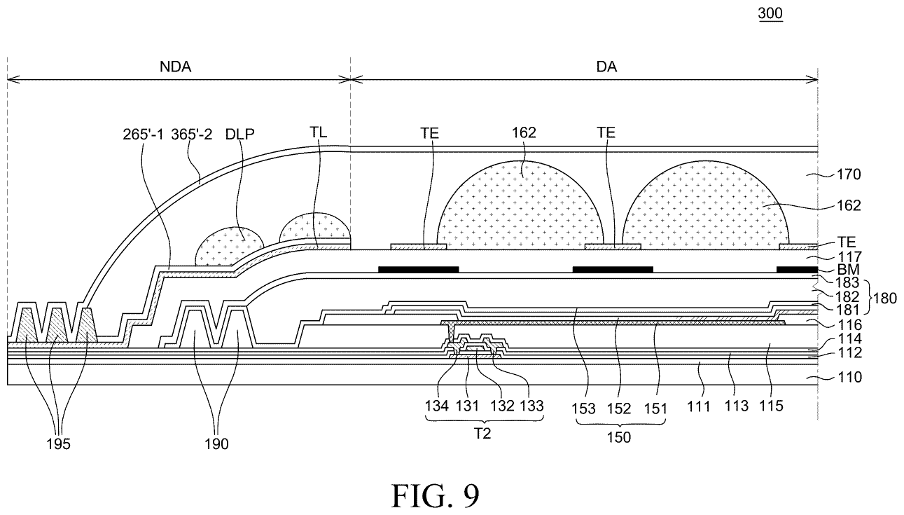

FIG. 9 is a cross-sectional view of a display device according to still another exemplary embodiment of the present disclosure.

Referring to FIG. 9, a display device 300 according to another exemplary embodiment of the present disclosure may include a substrate 110, a buffer layer 111, a gate insulating layer 112, an interlayer insulating layer 113, a lower protective layer 114, an overcoat layer 115, a first transistor T1, a second transistor T2, a first light emitting diode 140, a second light emitting diode 150, an encapsulation member 180, a touch insulating layer 117, a touch electrode TE, a first optical member 161, a second optical member 162, a protective film 165, a dummy optical member DLP, a first sub protective film 265′-1, a second sub protective film 365′-2, an organic layer 170, a touch routing line TL, a dam 190, and a partition 195. The display device 300 is substantially the same as the display device 200 which has been described with reference to FIG. 8 except for the position of the second sub protective film so that a description of repeated components will be omitted.

The first sub protective film 265′-1 is disposed on the touch routing line TL. The first sub protective film 265′-1 may be disposed so as to extend from the non-display area NDA adjacent to the display area DA to the outer edge of the non-display area NDA, but is not limited thereto. Therefore, in the present exemplary embodiment, the plurality of dummy optical members DLP are disposed on the first sub protective film 265′-1.

In the non-display area NDA, the organic layer 170 may be disposed so as to cover the plurality of dummy optical members DLP disposed on the first sub protective film 265′-1. The organic layer 170 is disposed so as to be in contact with the first sub protective film 265′-1 and the plurality of dummy optical members DLP.

The second sub protective film 365′-2 is disposed on the organic layer 170. The second sub protective film 365′-2 may be disposed on the organic layer 170 over the display area DA and the non-display area NDA as one layer. At least a part of the second sub protective film 365′-2 may be disposed on the partition 195, but the present disclosure is not limited thereto. If necessary, optionally, the second sub protective film 365′-2 may be disposed so as to correspond to the non-display area NDA.

In the exemplary embodiment, in the display device 300, the first sub protective film 265′-1 is disposed below the dummy optical member DLP and the second sub protective film 365′-2 is disposed on the organic layer 170 which is disposed so as to cover the dummy optical member DLP. Therefore, the dummy optical member DLP may be protected from the moisture or oxygen entering from the outside. Therefore, the deterioration of the dummy optical member DLP due to the moisture and oxygen is suppressed to further suppress the yellowing defect.

In the present exemplary embodiment, it is illustrated that the first sub protective film 265′-1 is disposed only in the non-display area NDA, but is not limited thereto. If necessary, the first sub protective film 265′-1 extends to the display area DA to be disposed on the touch insulating layer 117 and the touch electrode TE. In this case, each of the first optical member 161 and the second optical member 162 may be disposed on the first sub protective film 265′-1. When the first sub protective film 265′-1 is disposed below the first optical member 161 and the second optical member 162 as described above, the first optical member 161 and the second optical member 162 are protected from moisture or oxygen permeating from the outside to further improve the reliability.

Hereinafter, the effects of the present disclosure which have been described above will be described with reference to Exemplary Embodiments. However, the following Exemplary Embodiments are set forth to illustrate the present disclosure, but the scope of the present disclosure is not limited thereto.

### Experimental Embodiment 1

A relative luminance at each viewing angle was simulated on a sample. In the sample, on a light emitting cell including the first light emitting diode and a second light emitting diode, a first optical member which corresponded to a first light emitting diode and provided a viewing angle with a first value was located and a second optical member which corresponded to the second light emitting diode and provided a viewing angle with a second value which was lower than the first value was located. At this time, in a sample of Exemplary Embodiment, a SiNx protective film was provided on the first optical member and in a sample of Comparative Embodiment, a protective film was not provided. The relative luminance is a relative luminance in each area with respect to a center luminance. The result was represented in the following Table 1.

TABLE 1

| | | Exemplary | Comparative |
|---|---|---|---|
| | | Embodiment | Embodiment |
| Second | A+ Area Luminance | 52% | 52% |
| mode | A Area Luminance | 0% | 0% |
| (Privacy) | B Area Luminance | 0% | 0% |
| | Cut off angle(30°) | 9.1% | 9.1% |
| First | A+ Area Luminance | 91.2% | 90% |
| mode | A Area Luminance | 36% | 25% |
| (Share) | B Area Luminance | 24% | 23% |
| | Cut off angle(30°) | 9.5% | 9.1% |

Referring to Table 1, in both Exemplary Embodiment and Comparative Embodiment, it was confirmed that in the second mod which was a privacy mode, the luminance was the same, but in the first mode which was a share mode, a luminance of Exemplary Embodiment was higher than a luminance of Comparative Embodiment. It was understood that in Exemplary Embodiment, the SiNx protective film was located on the first optical member so that the luminance was improved. It was further confirmed that luminance values of 30° of Cut-off angle of Exemplary Embodiment and Comparative Embodiment were equal so that it was understood that the viewing angle control characteristic did not vary depending on whether the protective film was provided. Therefore, it was understood that when the protective film was provided on the first optical member, as illustrated in FIG. 4, the luminance difference due to the area difference between the first optical member area and the second optical member area may be improved while maintaining the viewing angle control characteristic.

### Experimental Embodiment 2

An anti-moisture permeability and the yellowing degree of each unit film with different laminated structure were evaluated. In Comparative Embodiment 2, an optical member was laminated on the substrate and in Exemplary Embodiment 2-1, an optical member was laminated on the substrate and the protective film was laminated so as to cover the optical member. Exemplary Embodiment 2-2 was a unit film in which a first protective film was laminated on the substrate, an optical member was disposed on the first protective film, and a second protective film was laminated so as to cover the optical member. The yellowing degree was measured after attaching a unit film on a 4500 nit panel and then storing the unit film for 336 hours at 85° C. The result was represented in Table 2.

TABLE 2

| | Comparative | Exemplary | Exemplary |
|---|---|---|---|
| | Embodiment 2 | Embodiment 2-1 | Embodiment 2-2 |
| Water | 43.8 | 9.2 × 10⁻⁵ | 8.7 × 10⁻⁶ |
| permeability | | | |
| (g/m2 · day) | | | |
| Yellowing | 5.48 | 0.05 | 0.03 |
| Degree | | | |

Referring to Table 2, in Comparative Embodiment 2 in which an optical member was disposed on the substrate, it was confirmed that the permeability was high so that it was vulnerable to moisture permeation so that the highest yellowing degree was obtained due to the deterioration of the optical member.

In contrast, in the case of Exemplary Embodiment 2-1 in which a protective film was laminated on the optical member, it was confirmed that the permeability was significantly reduced as compared with Comparative Embodiment 2 so that the yellowing degree was also significantly reduced. Moreover, in the case of Exemplary Embodiment 2-2 in which a protective film was formed on each of upper and lower portions of the optical member, it was confirmed that a permeability and yellowing degree lower than those of Exemplary Embodiment 2-1 were achieved.

Therefore, when the protective film was laminated on the optical member, it was understood that the anti-moisture permeability was significantly improved so that the yellowing degree was also significantly reduced. When the protective film was provided in each of the upper portion and the lower portion of the optical member, it was understood that both the permeability and the yellowing degree were further reduced to provide a display device with an improved reliability in a high temperature and high humidity environment.

### Experimental Embodiment 3

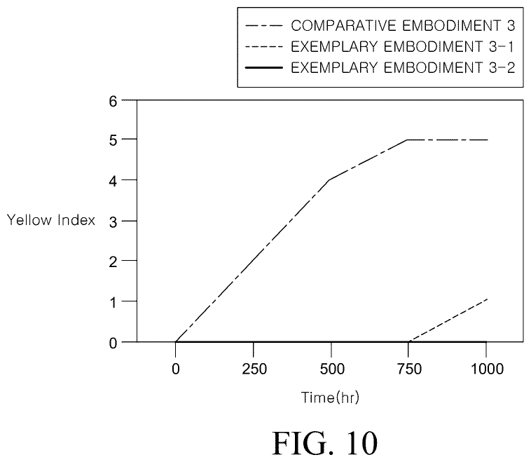

A yellowing degree of a panel was evaluated according to the presence of a protective film and a laminated structure of the protective film in a non-display area. Exemplary Embodiment 3-1, as illustrated in FIG. 7, was a panel having a structure in which a protective film was laminated above the dummy optical member. Exemplary Embodiment 3-2, as illustrated in FIG. 8, was a panel having a structure in which a protective film was laminated above and below the dummy optical member. Comparative Embodiment 3 was a panel with a structure in which a protective film laminated above the dummy optical member in Exemplary Embodiment 3-1 was omitted. The yellowing degree was measured at every 250 hours while storing the panel for 1000 hours at 85° C. in the driving condition of 375 nit. The result was represented in FIG. 10.

FIG. 10 is a graph illustrating a yellowing degree evaluation result of a panel according to Exemplary Embodiments 3-1 and 3-2 and Comparative Embodiment 3. Referring to FIG. 10, in Exemplary Embodiment 3-2 in which the protective film was laminated above and below the dummy optical member, the deterioration did not occur for 1000 hours in the high temperature condition, so that it was confirmed that the yellowing defect did not occur.

In Exemplary Embodiment 3-1 in which the protective film was laminated only above the dummy optical member, it was confirmed that the yellowing degree was increased after 750 hours, but the degree was insignificant.

In contrast, it was confirmed that in the panel of Comparative Embodiment 3 in which the protective film was not provided either above or below the dummy optical member, the yellowing degree was rapidly increased from the beginning of the experiment so that the reliability was inferior to those of panels of Exemplary Embodiments 3-1 and 3-2.

Therefore, it is understood that when the protective film is provided on a top surface of the dummy optical member, further, on a top surface and a bottom surface of the dummy optical member, the anti-moisture permeability of the display panel is improved so that the display device with excellent reliability may be provided.

The exemplary embodiments of the present disclosure can also be described as follows:

According to an aspect of the present disclosure, there is provided a display device. The display device includes a substrate which includes a display area in which a plurality of pixels including a plurality of sub pixels representing different colors is disposed and a non-display area which encloses the display area, a first light emitting diode and a second light emitting diode disposed in each of the plurality of sub pixels, a first optical member which is disposed so as to overlap an emission area of the first light emitting diode and provides a viewing angle with a first value, a plurality of second optical members which are disposed so as to overlap an emission area of the second light emitting diode and provides a viewing angle with a second value which is lower than the first value, and a protective film disposed on the first optical member.

The first light emitting diode and the second light emitting diode may include anodes, emission layers disposed on the anodes, and cathodes disposed on the emission layers, and the display device may further include bank insulating layers which cover edges of the anodes of the first light emitting diode and the second light emitting diode.

The display device may further comprise an encapsulation member disposed on the first light emitting diode and the second light emitting diode, a black matrix disposed on the encapsulation member, and a touch insulating layer disposed on the black matrix, wherein the black matrix may be disposed so as to overlap the bank insulating layer.

The display device may further comprise a plurality of touch electrodes which is disposed so as to overlap the bank insulating layer and the black matrix, above the black matrix, wherein the first optical member and the second optical member may be disposed so as to cover an edge of the touch electrode.

The protective film may be disposed to have a constant thickness along an upper surface of the first optical member.

The display device may further comprise at least one dam disposed in the non-display area, wherein the encapsulation member may include a first inorganic encapsulation layer, an organic encapsulation layer on the first inorganic encapsulation layer, and a second inorganic encapsulation layer on the organic encapsulation layer, and the first inorganic encapsulation layer and the second inorganic encapsulation layer may be disposed on the dam.

The display device may further comprise at least one partition disposed in the non-display area and disposed at an outer edge of the dam.

The display device may further comprise a touch routing line which is disposed on the same layer as the plurality of touch electrodes and extends from an area adjacent to the display area to an outer edge of the non-display area, wherein the partition may be disposed on the touch routing line.

The display device may further comprise at least one dummy optical member disposed on the touch routing line.

The display device may further comprise an organic layer which is disposed so as to cover the first optical member, the second optical member, and the dummy optical member.

The display device may further comprise a sub protective film which is disposed in at least one of an upper portion and a lower portion of the dummy optical member.

The sub protective film may be disposed so as to cover the dummy optical member and the touch routing line.

The sub protective film may include a first sub protective film disposed on a top surface of the touch routing line and a second sub protective film disposed to cover a top surface of the dummy optical member and the dummy optical member may be disposed on the first sub protective film.

The sub protective film may include a first sub protective film disposed on a top surface of the touch routing line and a second sub protective film disposed to cover a top surface of the organic layer and the dummy optical member may be disposed on the first sub protective film.

A refractive index of the protective film may be 1.9 or higher and 2.2 or lower and a thickness of the protective film may be 100 nm or larger and 200 nm or smaller.

The protective film may include one or more of a silicon nitride film (SiNx), a silicon oxide film (SiOx), and parylene.

The sub protective film may include one or more of a silicon nitride film (SiNx), a silicon oxide film (SiOx), and parylene.

A thickness of the sub protective film may be 100 nm or larger and 200 nm or smaller.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate which includes a display area in which a plurality of pixels including a plurality of sub pixels representing different colors is disposed and a non-display area which encloses the display area;
a first light emitting diode and a second light emitting diode disposed in each of the plurality of sub pixels;
a first optical member which is disposed so as to overlap an emission area of the first light emitting diode and provides a viewing angle with a first value;
a plurality of second optical members which are disposed so as to overlap an emission area of the second light emitting diode and provides a viewing angle with a second value which is lower than the first value; and
a protective film disposed on the first optical member.

2. The display device according to claim 1, wherein the first light emitting diode and the second light emitting diode include anodes, emission layers disposed on the anodes, and cathodes disposed on the emission layers, and the display device further includes bank insulating layers which cover edges of the anodes of the first light emitting diode and the second light emitting diode.

3. The display device according to claim 2, further comprising:
an encapsulation member disposed on the first light emitting diode and the second light emitting diode;
a black matrix disposed on the encapsulation member; and
a touch insulating layer disposed on the black matrix,
wherein the black matrix is disposed so as to overlap the bank insulating layer.

4. The display device according to claim 3, further comprising:
a plurality of touch electrodes which are disposed so as to overlap the bank insulating layer and the black matrix, above the black matrix,
wherein the first optical member and the second optical member are disposed so as to cover an edge of the touch electrode.

5. The display device according to claim 1, wherein the protective film is disposed to have a constant thickness along an upper surface of the first optical member.

6. The display device according to claim 4, further comprising:
at least one dam disposed in the non-display area,
wherein the encapsulation member includes a first inorganic encapsulation layer, an organic encapsulation layer on the first inorganic encapsulation layer, and a second inorganic encapsulation layer on the organic encapsulation layer, and the first inorganic encapsulation layer and the second inorganic encapsulation layer are disposed on the dam.

7. The display device according to claim 6, further comprising:
at least one partition disposed in the non-display area and disposed at an outer edge of the dam.

8. The display device according to claim 7, further comprising:
a touch routing line which is disposed on a same layer as the plurality of touch electrodes and extends from an area adjacent to the display area to an outer edge of the non-display area,
wherein the partition is disposed on the touch routing line.

9. The display device according to claim 8, further comprising:
at least one dummy optical member disposed on the touch routing line.

10. The display device according to claim 9, further comprising:
an organic layer which is disposed so as to cover the first optical member, the second optical member, and the dummy optical member.

11. The display device according to claim 10, further comprising:
a sub protective film which is disposed in at least one of an upper portion and a lower portion of the dummy optical member.

12. The display device according to claim 11, wherein the sub protective film is disposed so as to cover the dummy optical member and the touch routing line.

13. The display device according to claim 11, wherein the sub protective film includes a first sub protective film disposed on a top surface of the touch routing line and a second sub protective film disposed to cover a top surface of the dummy optical member and the dummy optical member is disposed on the first sub protective film.

14. The display device according to claim 11, wherein the sub protective film includes a first sub protective film disposed on a top surface of the touch routing line and a second sub protective film disposed to cover a top surface of the organic layer and the dummy optical member is disposed on the first sub protective film.

15. The display device according to claim 1, wherein a refractive index of the protective film is 1.9 or higher and 2.2 or lower and a thickness of the protective film is 100 nm or larger and 200 nm or smaller.

16. The display device according to claim 1, wherein the protective film includes one or more of a silicon nitride film (SiNx), a silicon oxide film (SiOx), and parylene.

17. The display device according to claim 11, wherein the sub protective film includes one or more of a silicon nitride film (SiNx), a silicon oxide film (SiOx), and parylene.

18. The display device according to claim 11, wherein a thickness of the sub protective film is 100 nm or larger and 200 nm or smaller.
